(19) United States
(12) Patent Application Publication
(10) Pub. No.: US 2016/0079416 A1
(43) Pub. Date: Mar. 17, 2016

(54) SEMICONDUCTOR DEVICE

(71) Applicant: Kabushiki Kaisha Toshiba, Tokyo (JP)

(72) Inventors: Koichi Sato, Nonoichi Ishikawa (JP); Kenya Kobayashi, Nonoichi Ishikawa (JP)

(21) Appl. No.: 14/635,922

(22) Filed: Mar. 2, 2015

(30) Foreign Application Priority Data
Sep. 16, 2014 (JP) 2014-187893

(51) Int. Cl. H01L 29/78; H01L 29/417; H01L 29/08; H01L 29/06; H01L 29/10

(52) U.S. Cl. CPC H01L 29/7823; H01L 29/0634; H01L 29/1095; H01L 29/0865; H01L 29/0878; H01L 29/41758; H01L 29/1033

(57) ABSTRACT

According to an embodiment, a semiconductor device includes first semiconductor layers and a second semiconductor layer disposed between adjacent first semiconductor layers. The first semiconductor layers have first end surfaces, and the second semiconductor layer has a second end surface between the adjacent first semiconductor layers. The device includes a first electrode facing each first end surface of the adjacent first semiconductor layers via an insulating film, a second electrode in contact with side surfaces of the adjacent first semiconductor layers and the second end surface, a first semiconductor region between the second electrode and the adjacent first semiconductor layers, and a second semiconductor region in the first semiconductor region between the second electrode and each of the adjacent first semiconductor layers. The first semiconductor region and the second semiconductor region face the first electrode via the insulating film, and electrically connected to the second electrode.

### CROSS-REFERENCE TO RELATED APPLICATIONS

This application is based upon and claims the benefit of priority from Japanese Patent Application No. 2014-187893, filed on Sep. 16, 2014; the entire contents of which are incorporated herein by reference.

### FIELD

Embodiments are related generally to a semiconductor device.

### BACKGROUND

A semiconductor device having the super-junction structure is preferably used in an application, such as power control to reduce on-resistance and to increase breakdown voltage. The super-junction structure is formed in the drift layer of a MOSFET (metal oxide semiconductor field effect transistor), for example. In the super-junction structure, n-type semiconductor regions and p-type semiconductor regions are alternately arranged in the direction perpendicular to the current flowing therethrough. The on-resistance may be reduced by narrowing the repetition pitch of the n-type semiconductor regions and the p-type semiconductor regions. Such a reducing of the on-resistance, however, may become difficult due to the limit of fine patterning in the manufacturing process of the semiconductor device.

### BRIEF DESCRIPTION OF THE DRAWINGS

FIGS. 1A and 1B are schematic views showing a semiconductor device according to a first embodiment;

FIG. 2 is a schematic view showing a main portion of the semiconductor device according to the first embodiment;

FIG. 3 is a graph showing a characteristic of the semiconductor device according to the first embodiment;

FIGS. 4A to 13C are schematic cross-sectional views showing a manufacturing process of the semiconductor device according to the first embodiment; and

FIGS. 14A to 21C are schematic cross-sectional views showing a manufacturing process of a semiconductor device according to a second embodiment.

### DETAILED DESCRIPTION

According to an embodiment, a semiconductor device includes an underlying layer, first semiconductor layers of a first conductivity type arranged in a first direction perpendicular to the underlying layer, and a second semiconductor layer disposed between adjacent first semiconductor layers. The first semiconductor layers have first end surfaces, and the second semiconductor layer has a second end surface between the adjacent first semiconductor layers. The device further includes a first electrode facing each first end surface of the adjacent first semiconductor layers via an insulating film, a second electrode in contact with side surfaces of the adjacent first semiconductor layers and the second end surface, a first semiconductor region of the second conductivity type between the second electrode and each of the adjacent first semiconductor layers, and a second semiconductor region of the first conductivity type in the first semiconductor region between the second electrode and each of the adjacent first semiconductor layers. The first semiconductor region faces the first electrode via the insulating film. The second semiconductor region faces the first electrode via the insulating film, and electrically connected to the second electrode.

Embodiments will now be described with reference to the drawings. The same portions inside the drawings are marked with the same numerals; a detailed description is omitted as appropriate; and the different portions are described. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated. There are cases where the dispositions of the components are described using the directions of XYZ axes shown in the drawings. The X-axis, the Y-axis, and the Z-axis are orthogonal to each other. Hereinbelow, the directions of the X-axis, the Y-axis, and the Z-axis are described as an X-direction, a Y-direction, and a Z-direction. Also, there are cases where the Z-direction is described as upward and the direction opposite to the Z-direction is described as downward.

### First Embodiment

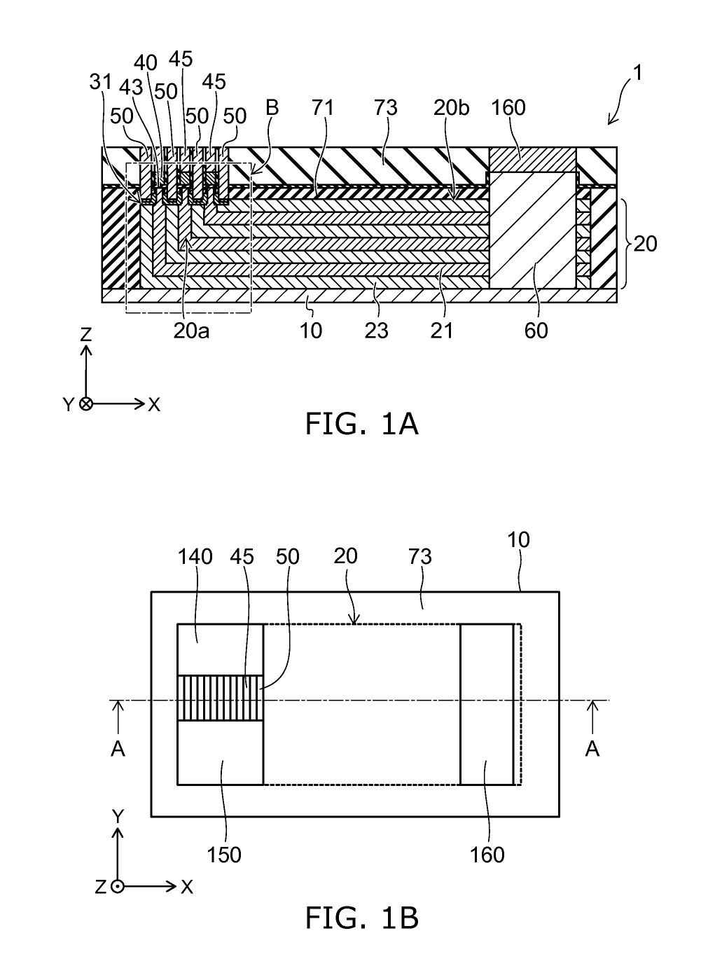

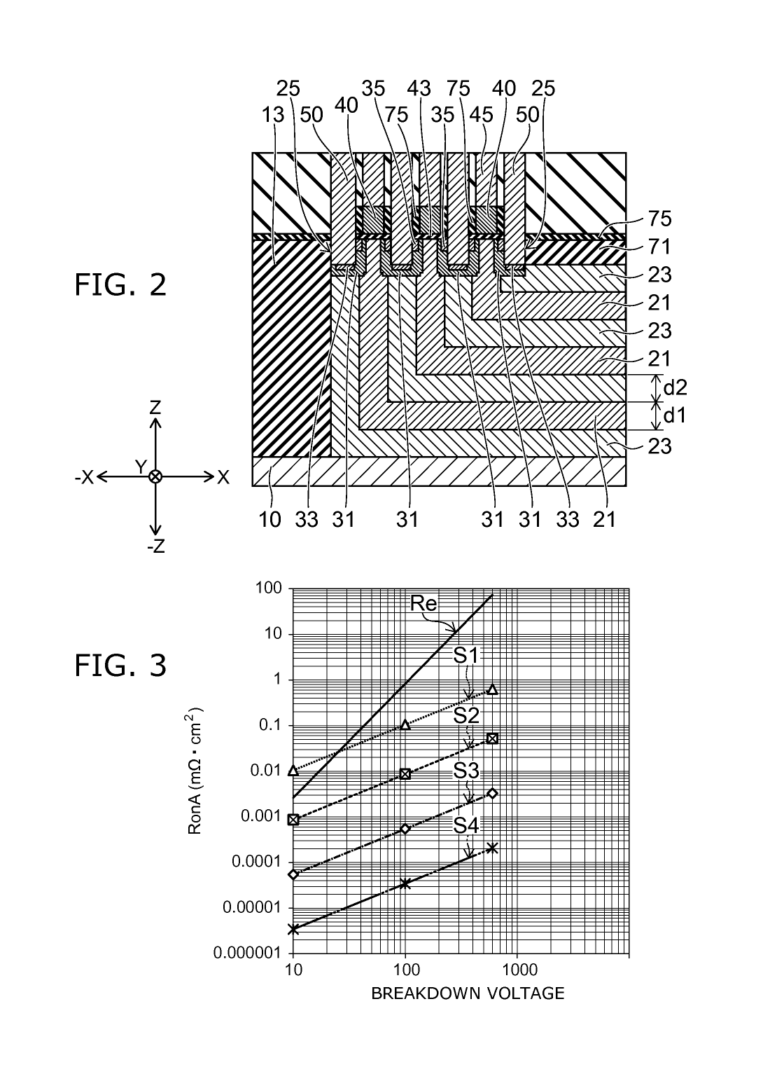

A semiconductor device 1 according to an embodiment is described with reference to FIGS. 1A to 2. The semiconductor device 1 is, for example, a lateral MOSFET used for power control.

FIGS. 1A and 1B are schematic views illustrating the semiconductor device 1. FIG. 1A is a cross-sectional view showing a structure of the semiconductor device 1. FIG. 1B is a plan view showing the upper surface of the semiconductor device 1. FIG. 1A is a cross-sectional view taken along line A-A shown in FIG. 1B.

As shown in FIG. 1A, the semiconductor device 1 includes a semiconductor layer 10 and a stacked body 20 provided thereon. The semiconductor layer 10 is an underlying layer. The semiconductor layer 10 is a silicon layer or a silicon substrate, for example. The semiconductor layer 10 has a higher electrical resistance than an electrical resistance of the stacked body 20.

The stacked body 20 has a structure in which n-type semiconductor layers 21 (first semiconductor layers) and p-type semiconductor layers 23 (second semiconductor layers) are alternately stacked in the Z-direction. The stacked body 20 is provided so that the total amount of n-type impurities is balanced with the total amount of p-type impurities, for example. That is, the stacked body 20 has a super-junction structure.

In the super-junction structure, for instance, the drift current is passed through the n-type semiconductor layers 21 in the ON-state, which is doped with n-type impurities at relatively high concentration. Thus, the on-resistance is reduced. In the OFF-state, the n-type semiconductor layers 21 and the p-type semiconductor layers 23 are entirely depleted by balancing the total amounts of the n-type impurity and the p-type impurity, thus providing the high breakdown voltage.

A rising part 20a is provided at an end of the stacked body 20 in the X-direction. In the rising part 20a, the n-type semiconductor layers 21 and the p-type semiconductor layers 23 extend in the Z-direction, for example. A gate electrode 40 (first electrode) is provided via a gate insulating film 43 at an upper end of the n-type semiconductor layer 21 in the Z-direction. The gate electrode 40 is electrically connected to a gate interconnection 45.

A p-type base region 31 is provided at the upper end of the p-type semiconductor layer 23. The p-type semiconductor layer 23 is electrically connected to a source electrode 50 (second electrode) via the p-type base region 31.

An n-type drain layer 60 (third semiconductor layer) is provided at the other end of the stacked body 20 in the X-direction. The n-type drain layer 60 is provided on the semiconductor layer 10. The n-type drain layer 60 is in contact with the n-type semiconductor layers 21 and the p-type semiconductor layers 23. A drain electrode 160 (third electrode) is provided on the upper surface of the n-type drain layer 60.

The semiconductor device 1 includes an insulating film 71 covering the upper surface 20b of the stacked body 20, and an insulating film 73 provided on the insulating film 71.

As shown in FIG. 1B, a source pad 140, a gate pad 150, and a drain electrode 160 are arranged on the upper surface of the semiconductor device 1. The source pad 140 is electrically connected to the source electrode 50. The gate pad 150 is electrically connected to the gate electrode via the gate interconnection 45. The stacked body 20 has a quadrangular shape in a top-view thereof.

FIG. 2 is a schematic sectional view showing the main part of the semiconductor device 1. FIG. 2 is an enlarged view of the part B shown in FIG. 1A.

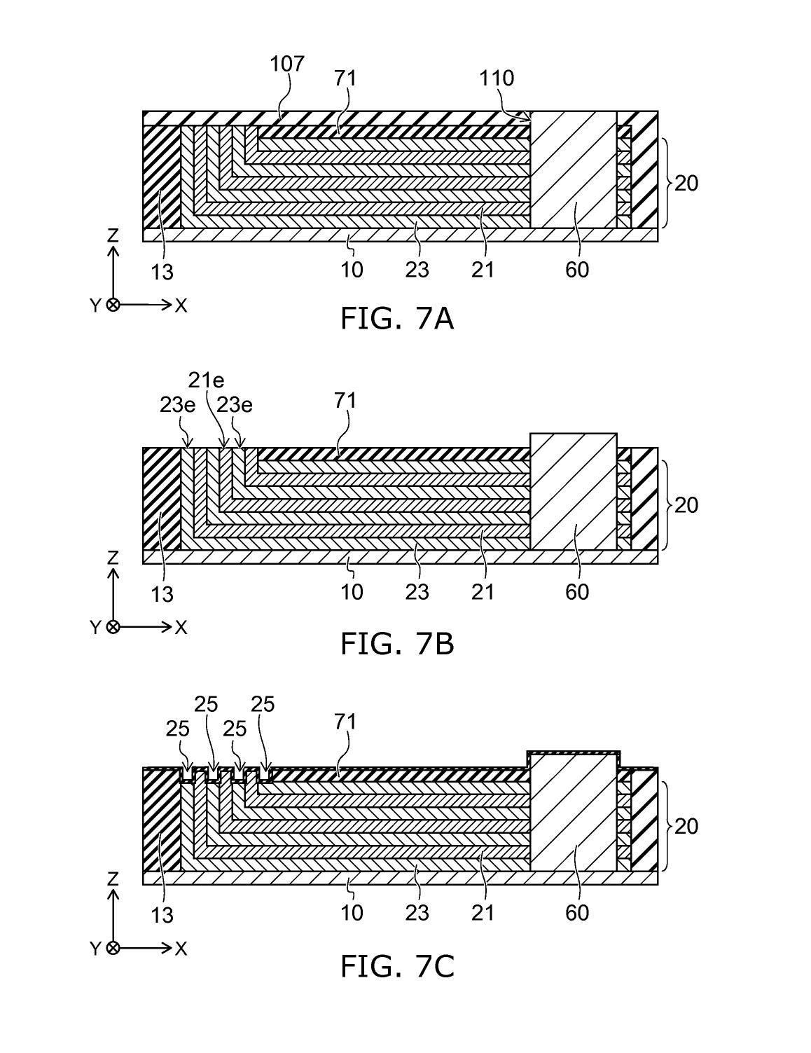

As shown in FIG. 2, a trench 25 is provided in the upper part of the p-type base region 31. The trench 25 is formed by selectively etching the upper end of the p-type semiconductor layer 23 (see FIG. 7C). The trench 25 is provided so that the p-type base region 31 is also formed in the lower side surface of the trench 25. The source electrode 50 is provided inside the trench 25. The source electrode 50 is electrically connected to the p-type base region 31. Here, the upper end of the p-type semiconductor layer 23 is set back in a reverse direction of the Z-direction from the upper end of the n-type semiconductor layer 21. The lower part of the source electrode 50 is located between the adjacent n-type semiconductor layers 21. Thus, the p-type base region 31 is provided in contact with the upper end of the p-type semiconductor layer 23 and the side surface of the n-type semiconductor layer 21 via the p-type base region 31 in vicinity of the upper end thereof.

A p-type contact region 33 is provided between the source electrode 50 and a part of the p-type base region 31 provided on the upper end of the p-type semiconductor layer 23. Further, an n-type source region 35 is selectively provided in a part of the p-type base region 31 that is located between the n-type semiconductor layer 21 and the source electrode 50. The part of the p-type base region 31 has an extending part between the n-type semiconductor layer 21 and the n-type source region 35. The p-type contact region 33 and the n-type source region 35 are in contact with the source electrode 50. The p-type impurity concentration of the p-type contact region 33 is higher than the p-type impurity concentration of the p-type base region 31. Furthermore, the n-type impurity concentration of the n-type source region 35 is higher than the n-type impurity concentration of the n-type semiconductor layer 21.

The semiconductor device 1 is turned on when applying a gate bias to the gate electrode 40. An inversion layer is formed in the p-type base region 31 at an interface between the gate insulating film 43 and the p-type base region 31. The n-type source region 35 and the n-type semiconductor layer 21 are connected via the inversion layer, and electron current flows from the source electrode 50 to the n-type semiconductor layer 21. That is, the current flows from the drain electrode 160 through the n-type semiconductor layer 21 to the source electrode 50. The current flows in a reverse direction of the X-direction inside the stacked body 20. Thus, the semiconductor device 1 operates as a lateral MOSFET.

FIG. 3 shows a graph illustrating the characteristics of the semiconductor device 1. The vertical axis represents RonA (mΩ·cm²). The horizontal axis represents the source-drain breakdown voltage. Here, RonA is the product of the on-resistance “Ron” and the effective area “A” of the device. The breakdown voltage (V) represents the breakdown voltage due to the avalanche breakdown.

S1-S4 shown in FIG. 3 represent the relationship between RonA and breakdown voltage for different repetition pitches (d₁+d₂: see FIG. 2) of the n-type semiconductor layers 21 and the p-type semiconductor layers 23. “Re” represents the relationship between RonA and breakdown voltage for a bulk crystal of silicon. The repetition pitch of S1 is 8 micrometers (μm). The repetition pitch of S2 is 1 μm. The repetition pitch of S3 is 0.1 μm. The repetition pitch of S4 is 0.01 μm.

As shown in FIG. 3, RonA becomes smaller in a structure having the super-junction than that in the bulk crystal of silicon. Furthermore, it is found that RonA can be reduced in the super-junction structure by decreasing the repetition pitch of the n-type semiconductor layers 21 and the p-type semiconductor layers 23.

For example, a vertical MOSFET which has electrodes on the upper/lower sides can also comprises the super-junction structure having a repetition pitch of 1 μm or more. That is, the vertical super-junction can be formed with a repetition pitch of 1 μm or more, wherein p-type semiconductors and n-type semiconductors can be alternately arranged in the direction parallel to the semiconductor substrate or semiconductor layer. For a repetition pitch smaller than 1 μm, however, it becomes difficult to form the vertical super-junction structure due to a difficulty of forming an ion implantation mask using photolithography, for example. Thus, in the vertical MOSFET, it is difficult to realize the lower on-resistance that is achieved in a fine repetition pitch range.

In the lateral MOSFET like the semiconductor device 1, the n-type semiconductor layers 21 and the p-type semiconductor layers 23 can be stacked alternately using epitaxial growth. Thus, the repetition pitch d₁+d₂ of the n-type semiconductor layers 21 and the p-type semiconductor layers 23 may be precisely controlled using epitaxial growth. That is, a desired repetition pitch can be achieved by adjusting the thickness of the epitaxially grown semiconductor layers. Further, it is easy in an epitaxial growth of silicon to control the layer thickness less than 1 μm. Thus, the semiconductor device 1 may comprise the super-junction with the repetition pitch that is unfeasible in the vertical MOSFET, and achieve the lower on-resistance.

The source electrode 50 is in contact with the p-type contact region 33 and the n-type source region 35 inside the trench 25. The on-resistance may be further reduced by reducing each contact resistance, and the avalanche breakdown voltage may also be improved in the semiconductor device 1.

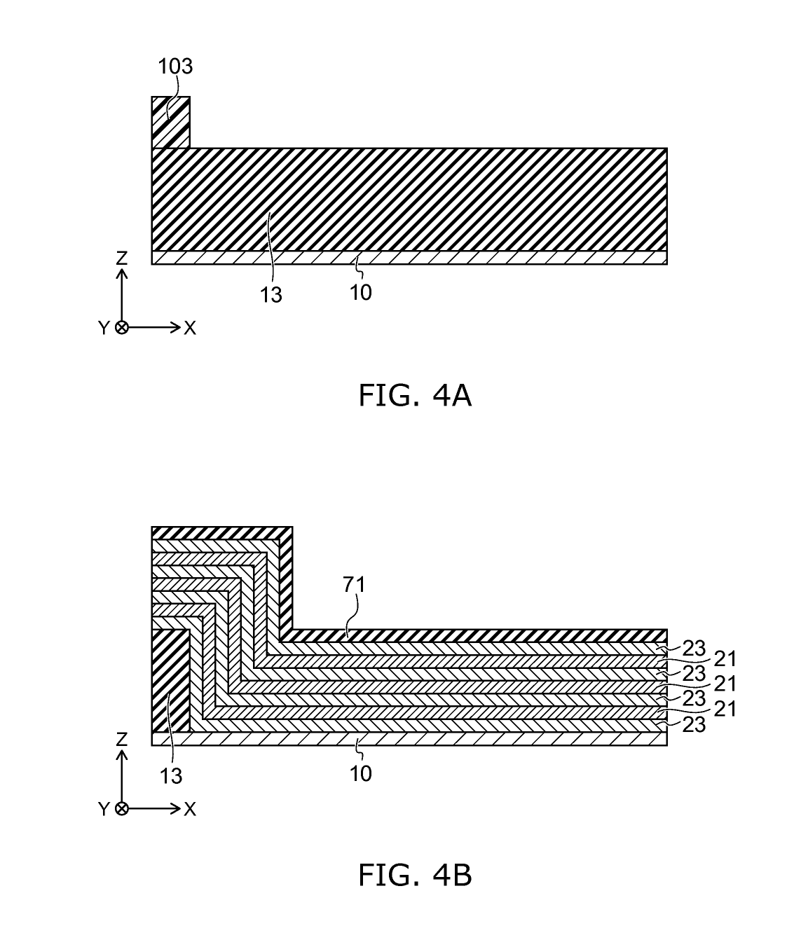

Next, a method for manufacturing the semiconductor device 1 is described with reference to FIGS. 4A to 13C. FIGS. 4A to 13C are schematic sectional views illustrating the process for manufacturing a semiconductor device according to the first embodiment.

As shown in FIG. 4A, an insulating film 13 is formed on a semiconductor layer 10. The insulating film 13 is e.g. a silicon nitride film. Furthermore, a resist film 103 is formed on a part of the insulating film 13.

The resist film 103 is used as a mask to selectively etch the insulating film 13. Thus, the semiconductor layer 10 is exposed. Then, n-type semiconductor layers 21 and p-type semiconductor layers 23 are alternately formed on the semiconductor layer 10.

As shown in FIG. 4B, the n-type semiconductor layers 21 and the p-type semiconductor layers 23 are formed on the semiconductor layer 10 and on the insulating film 13. The n-type semiconductor layers 21 and the p-type semiconductor layers 23 are formed along the side surface of the insulating film 13.

The n-type semiconductor layers 21 and the p-type semiconductor layers 23 are epitaxially grown silicon layers, for example. The n-type semiconductor layers 21 and the p-type semiconductor layers 23 are formed so as to balance the total amount of n-type impurities and the total amount of p-type impurities contained therein.

An insulating film 71 is formed on the uppermost p-type semiconductor layer 23. The insulating film 71 preferably has a portion at the same level with the upper surface of the insulating film 13. The insulating film 71 is a silicon nitride film, for example, and serves as a stopper against CMP (chemical mechanical polishing). The insulating film 71 is made of the same material as the insulating film 13.

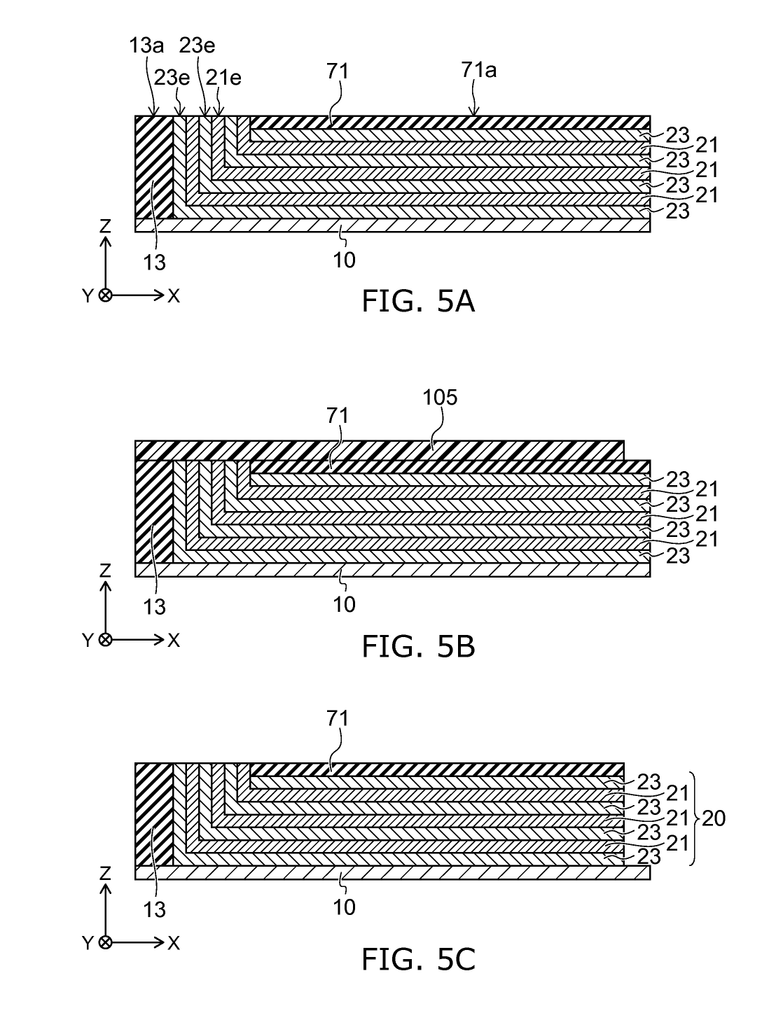

As shown in FIG. 5A, the upper end surfaces of the stacked structure of the n-type semiconductor layers 21 and the p-type semiconductor layers 23 is planarized between the insulating film 13 and 71. For instance, the portion of the stacked structure formed on the insulating film 13 is removed using CMP. The insulating film 13 and the insulating film 71 act as a stopper in the polishing process. Thus, the upper surface 13a of the insulating film 13 and the upper surface 71a of the insulating film 71 are formed in plane with the end surfaces of the n-type semiconductor layers 21 and the p-type semiconductor layers 23. The upper end 21e (first end surface) of the n-type semiconductor layer 21 and the upper end 23e (second end surface) of the p-type semiconductor layer 23 are formed between the insulating film 13 and the insulating film 71. The upper end 21e of the n-type semiconductor layer 21 and the upper end 23e of the p-type semiconductor layer 23 are formed in a plane parallel to the semiconductor layer 10.

As shown in FIG. 5B, a resist film 105 is formed to cover the insulating film 13, the upper end 21e of the n-type semiconductor layers 21, the upper end 23e of the p-type semiconductor layers 23, and part of the insulating film 71.

The insulating film 71, the n-type semiconductor layers 21, and the p-type semiconductor layers 23 are selectively etched to form a stacked body 20 as shown in FIG. 5C.

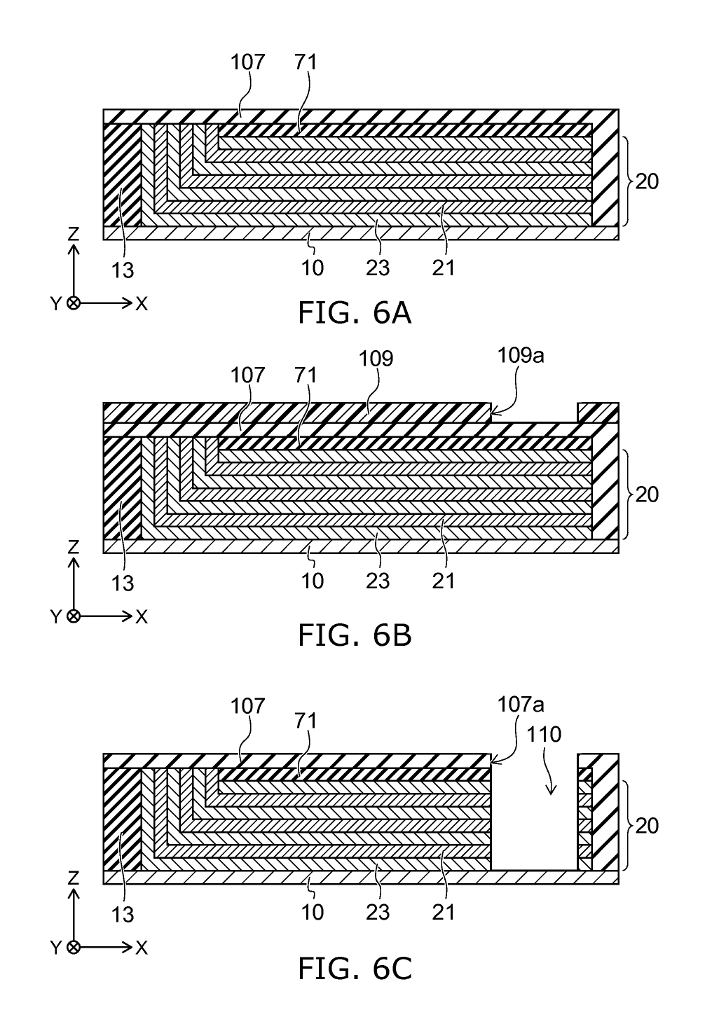

As shown in FIG. 6A, an insulating film 107 is formed to cover the stacked body 20 and the insulating film 13. The insulating film 107 is a silicon oxide film, for example.

As shown in FIG. 6B, a resist film 109 is formed on the insulating film 107. The resist film 109 has an opening 109a.

The resist film 109 is used as a mask to selectively etch the insulating film 107, thus, providing an opening 107a. The insulating film 107 is used as an etching mask to selectively remove the insulating film 71, the n-type semiconductor layers 21, and the p-type semiconductor layers 23. Thus, a trench 110 is formed as shown in FIG. 6C. The trench 110 is formed with a depth from the insulating film 71 to the semiconductor layer 10. The trench 110 also extends in the Y-direction.

As shown in FIG. 7A, an n-type drain layer 60 is formed in the trench 110. For example, an n-type silicon layer is formed on the insulating film 107 to fill the trench 110. Then, the n-type silicon layer is etched back, leaving an n-type drain layer 60 in the trench 110. The n-type drain layer 60 contains n-type impurities of higher concentration than that of the n-type semiconductor layer 21.

As shown in FIG. 7B, the insulating film 107 is etched back to expose the upper end 21e of the n-type semiconductor layers 21 and the upper end 23e of the p-type semiconductor layers 23.

As shown in FIG. 7C, the p-type semiconductor layer 23 is selectively etched to form trenches 25. The depth of the trench 25 is equal to the film thickness of the insulating film 71, for example.

An insulating film 113 is formed to cover the inner surface of the trench 25 and the insulating film 13, 71. The insulating film 113 is a silicon oxide film, for example. Then, an insulating film 115 is formed on the insulating film 113. The insulating film 115 fills the inside of the trench 25. The insulating film 115 is a silicon oxide film, for example.

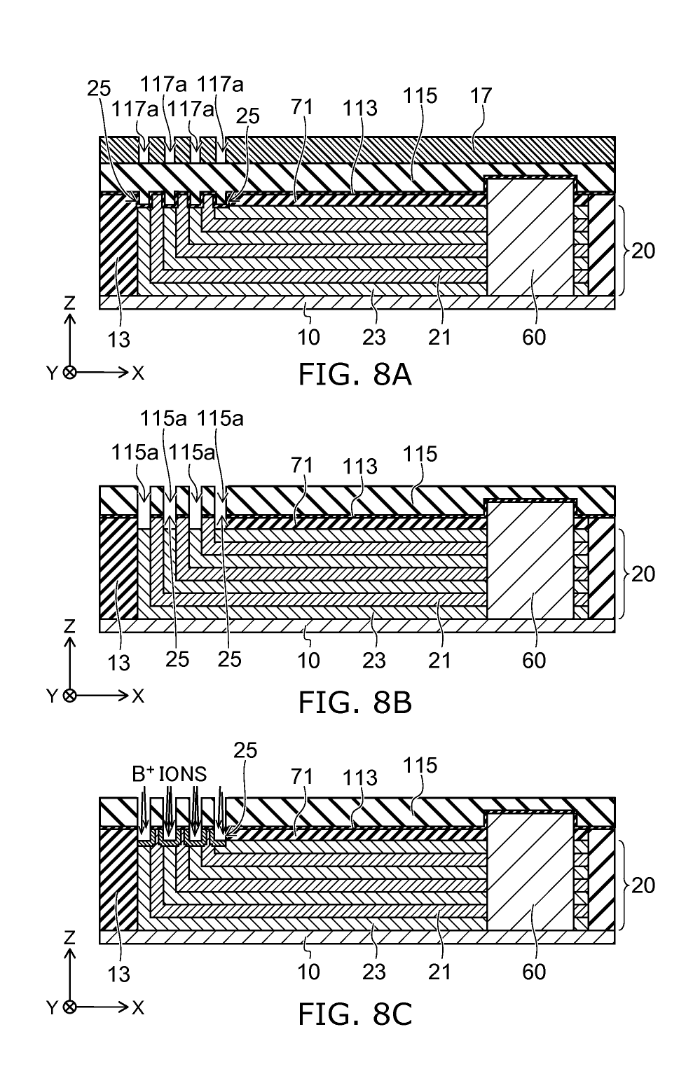

As shown in FIG. 8A, a resist film 117 is formed on the insulating film 115. The resist film 117 has an opening 117a above the trench 25. Then, the insulating film 115 and the insulating film 113 are selectively etched using the resist film 117 as an etching mask. Subsequently, the resist film 117 is removed.

As shown in FIG. 8B, a plurality of trenches 115a are formed in the insulating film 115. The trench 25 is reproduced in the lower part of the trench 115a. The trench 115a is in communication with the trench 25.

As shown in FIG. 8C, p-type impurities such as boron (B) are ion-implanted into the inner surface of the trench 25.

Then, the insulating film 115 and the insulating film 113 are removed. Subsequently, the ion-implanted p-type impurity is activated by heat treatment to form a p-type base region 31 in the inner surface of the trench 25.

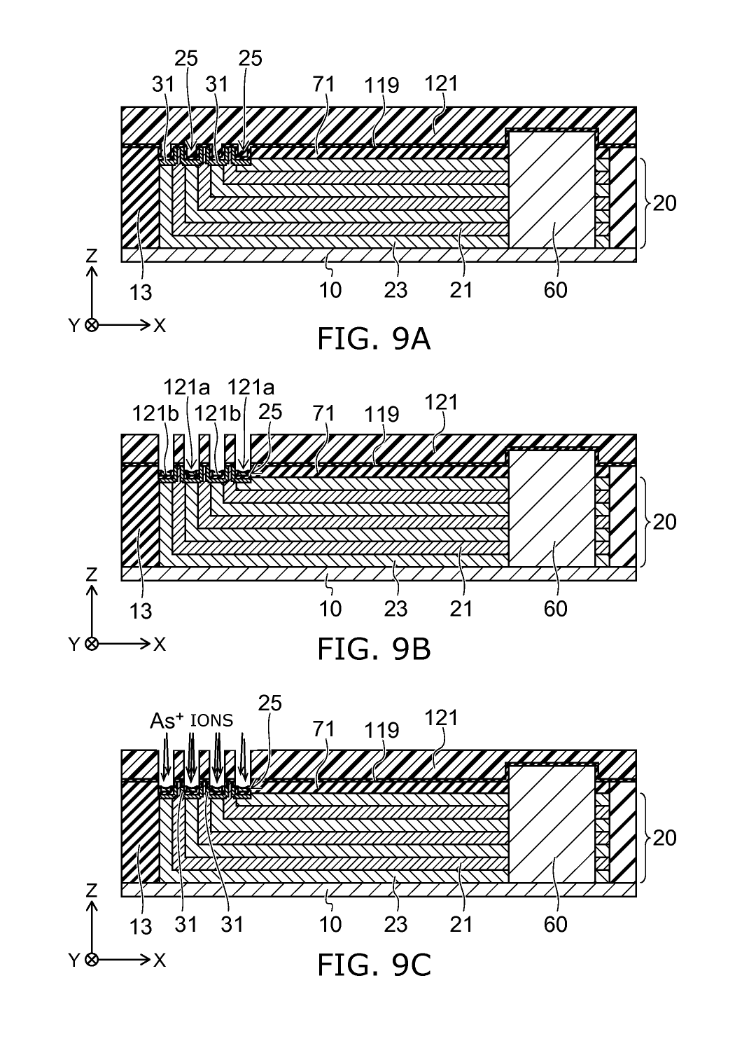

As shown in FIG. 9A, an insulating film 119 is formed to cover the inner surface of the trench 25 and the insulating film 13, 71. The insulating film 119 is a silicon oxide film, for example. Then, a resist film 121 is formed on the insulating film 119 to fill the inside of the trench 25.

As shown in FIG. 9B, a portion of the resist film 121 above the trench 25 is selectively etched back to form an opening 121a, leaving a part 121b of the resist film 121 at the bottom of the opening 121a, and to expose the upper end of the p-type base region 31.

As shown in FIG. 9C, n-type impurities such as arsenic (As) are ion-implanted into the sidewall of the trench 25 via the opening 121a. Then, the resist film 121 and the insulating film 119 are removed, and the ion-implanted n-type impurities are activated by heat treatment to form an n-type source region 35. The n-type source region 35 is formed at the upper end of the p-type base region 31.

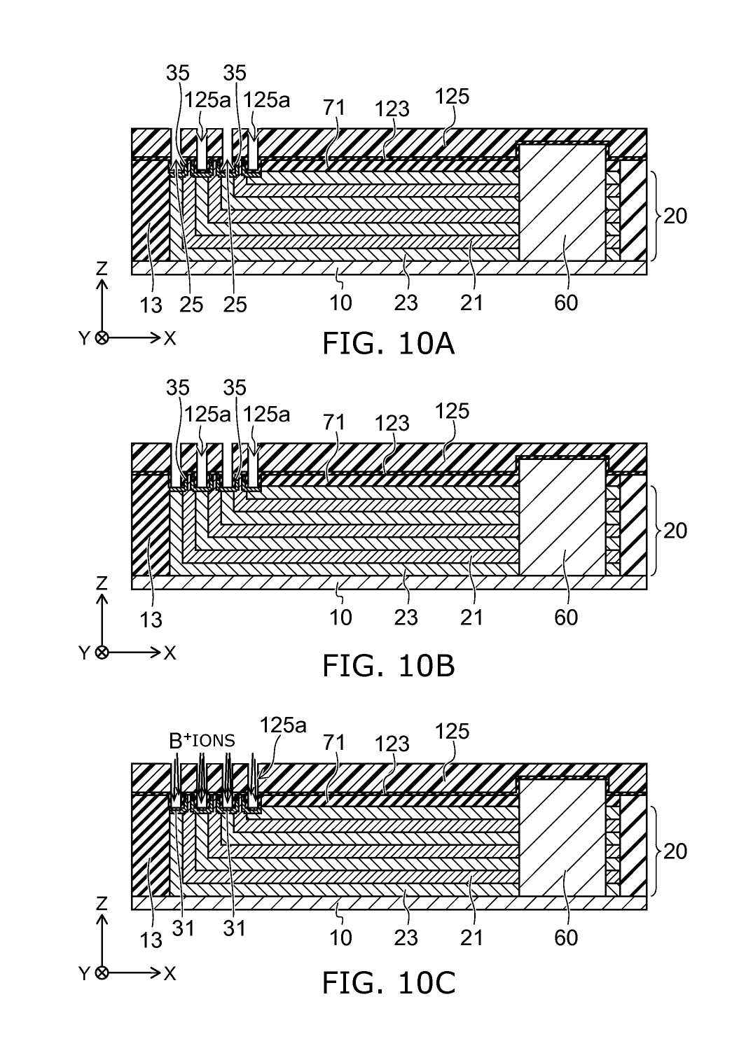

As shown in FIG. 10A, an insulating film 123 is formed to cover the inner surface of the trench 25 and the insulating film 13, 71. The insulating film 123 is a silicon oxide film, for example. Subsequently, a resist film 125 is formed on the insulating film 123. The resist film 125 has an opening 125a in communication with the trench 25.

As shown in FIG. 10B, a portion on the bottom surface of the trench 25, of the insulating film 123 is removed via the opening 125a.

As shown in FIG. 10C, p-type impurities such as boron (B) are ion-implanted into the p-type base region 31 through the opening 125a. The p-type impurities are implanted into the p-type base region 31 at the bottom surface of the trench 25.

Then, the resist film 125 and the insulating film 123 are removed. Subsequently, the ion-implanted p-type impurities are activated by heat treatment to form a p-type contact region 33.

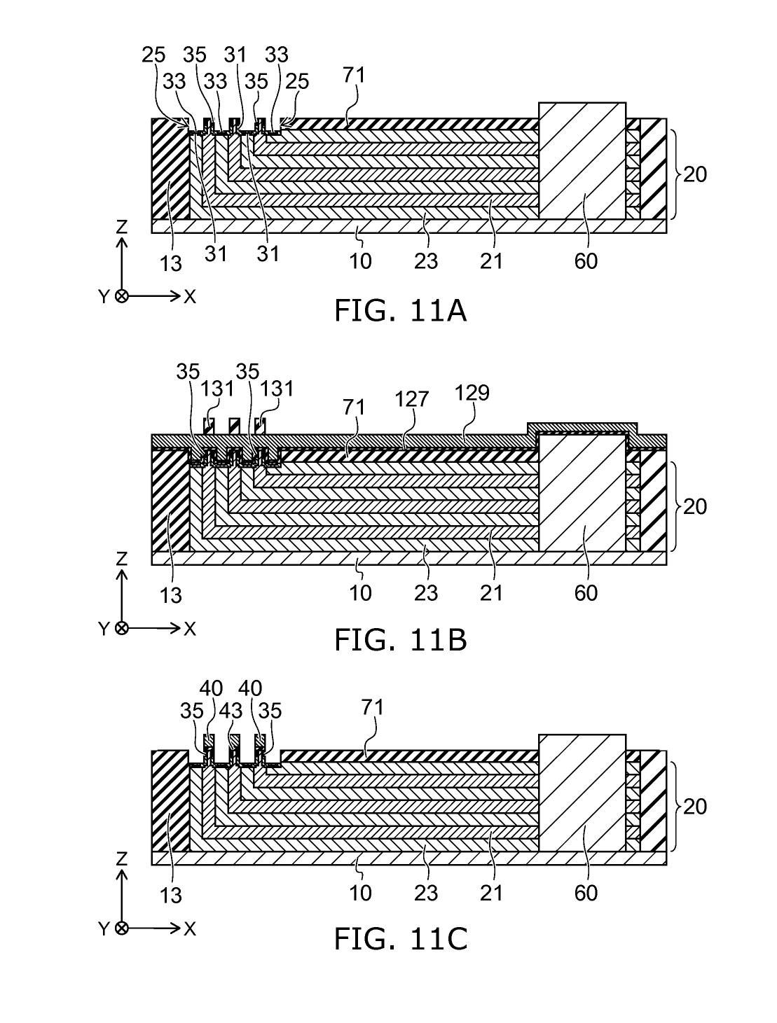

As shown in FIG. 11A, the p-type contact region 33 is formed on the p-type base region 31 at the bottom surface of the trench 25.

As shown in FIG. 11B, an insulating film 127 is formed to cover the inner surface of the trench 25 and the insulating film 13, 71. The insulating film 127 is a silicon oxide film, for example. Then, a conductive film 129 is formed on the insulating film 127. The conductive film 129 is a conductive polysilicon film, for example. Then, a resist film 131 is formed on the conductive film 129. The resist film 131 is formed above the n-type semiconductor layer 21.

The conductive film 129 and the insulating film 127 are selectively removed using the resist film 131 as an etching mask.

As shown in FIG. 11C, a gate electrode 40 and a gate insulating film 43 are formed on the n-type semiconductor layer 21. The gate electrode 40 is a part of the conductive film 129. The gate insulating film 43 is a part of the insulating film 127.

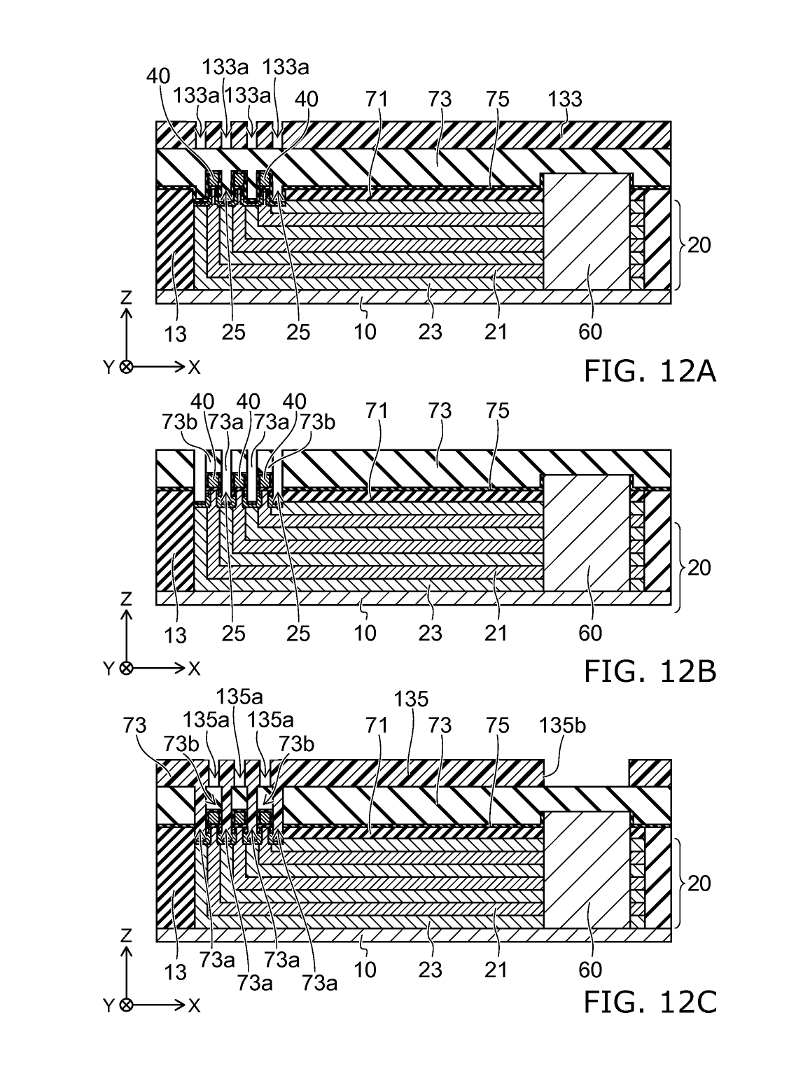

As shown in FIG. 12A, an insulating film 75 is formed to cover the inner surface of the trench 25, the gate electrode 40, the insulating films 13 and 71. The insulating film 75 is a silicon oxide film, for example. Then, an insulating film 73 is formed on the insulating film 75. The insulating film 73 is formed so as to fill the inside of the trench 25. The insulating film 73 is a silicon oxide film, for example. Subsequently, a resist film 133 is formed on the insulating film 73. The resist film 133 has an opening 133a formed above the trench 25.

Then, the insulating film 73 is selectively removed using the resist film 133 as an etching mask to form a trench 73a. As shown in FIG. 12B, the trench 73a is in communication with the trench 25. That is, a portion filling the inside of the trench 25 is removed in the insulating film 73. Thus, a part 73b of the insulating film 73 is left on the gate electrode 40.

Further, a portion of the insulating film 75 covering the inner surface of the trench 25 is removed. For example, isotropic dry etching is used to remove the portion exposed in the inner surface of the trench 25, leaving the portion covering the gate electrode 40.

Then, a resist film 135 is formed to cover the insulating film 73, filling the inside of the trench 73a. Subsequently, as shown in FIG. 12C, openings 135a and 135b are formed in the resist film 135. The opening 135a is in communication with a portion 73b of the insulating film 73 on the gate electrode 40. The opening 135b is formed above the n-type drain layer 60.

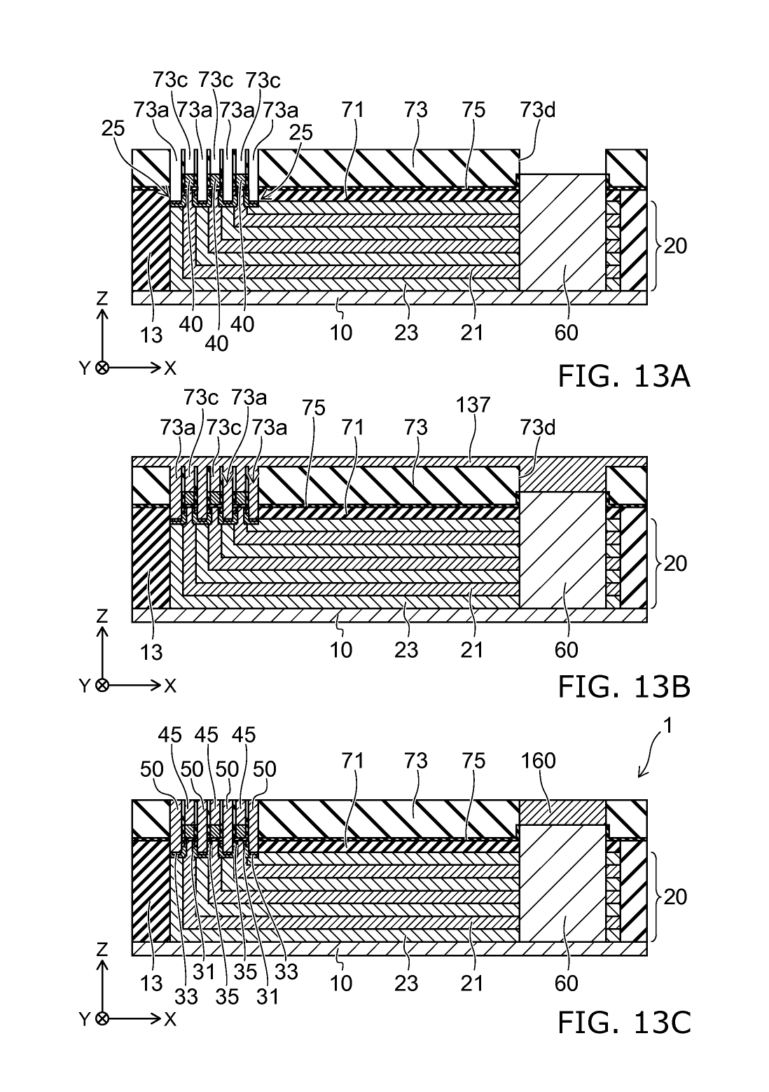

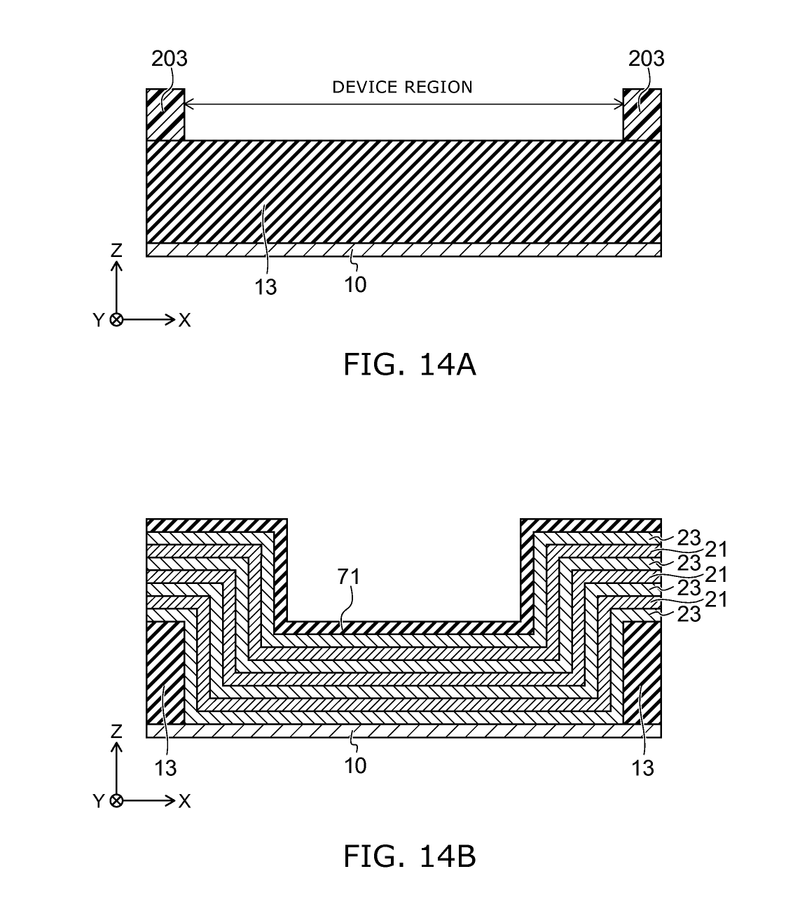

Then, the insulating film 73 is removed using the resist film 135 as an etching mask. Thus, as shown in FIG. 13A, trenches 73a, 73c, and 73d is formed in the insulating film 73. The trench 73a is in communication with the trench 25. The trench 73c is in communication with the gate electrode 40. The trench 73d is in communication with the n-type drain layer 60.

As shown in FIG. 13B, a metal film 137 is formed to cover the insulating film 73. The metal film 137 is a tungsten film, for example. The metal film 137 may be a stacked film including a titanium nitride (TiN) film on the insulating film 73 and a tungsten film on the TiN film.

Then, the metal film 137 on the insulating film 73 is removed, leaving a portion embedded in the trenches 73a, 73c, and 73d. For example, the metal film 137 may be polished using CMP. Alternatively, the metal film 137 may be etched back until the insulating film 73 is exposed. Thus, a gate interconnection 45, a source electrode 50, and a drain electrode 160 are formed. Thus, the semiconductor device 1 is completed as shown in FIG. 13C.

### Second Embodiment

Next, a method for manufacturing a semiconductor device 2 according to a second embodiment is described. FIGS. 14A to 21C are schematic cross-sectional views showing the manufacturing process of the semiconductor device 2.

As shown in FIG. 14A, an insulating film 13 is formed on a semiconductor layer 10. Then, a resist film 203 is formed on the insulating film 13. The resist film 203 is provided so as to surround the device region.

The insulating film 13 is removed using resist film 203 as an etching mask. Thus, the semiconductor layer 10 is exposed. Then, n-type semiconductor layers 21 and p-type semiconductor layers 23 are alternately formed thereon.

As shown in FIG. 14B, the n-type semiconductor layers 21 and the p-type semiconductor layers 23 are formed on the semiconductor layer 10 and on the insulating film 13. The n-type semiconductor layers 21 and the p-type semiconductor layers 23 are also formed along a side surface of the insulating film 13. The n-type semiconductor layers 21 and the p-type semiconductor layers 23 are formed so as to balance the total amount of n-type impurities and the total amount of p-type impurities contained therein.

An insulating film 71 is formed on the uppermost p-type semiconductor layer 23. A part of the insulating film 71 is preferably provided at the same level as the upper surface 13a of the insulating film 13.

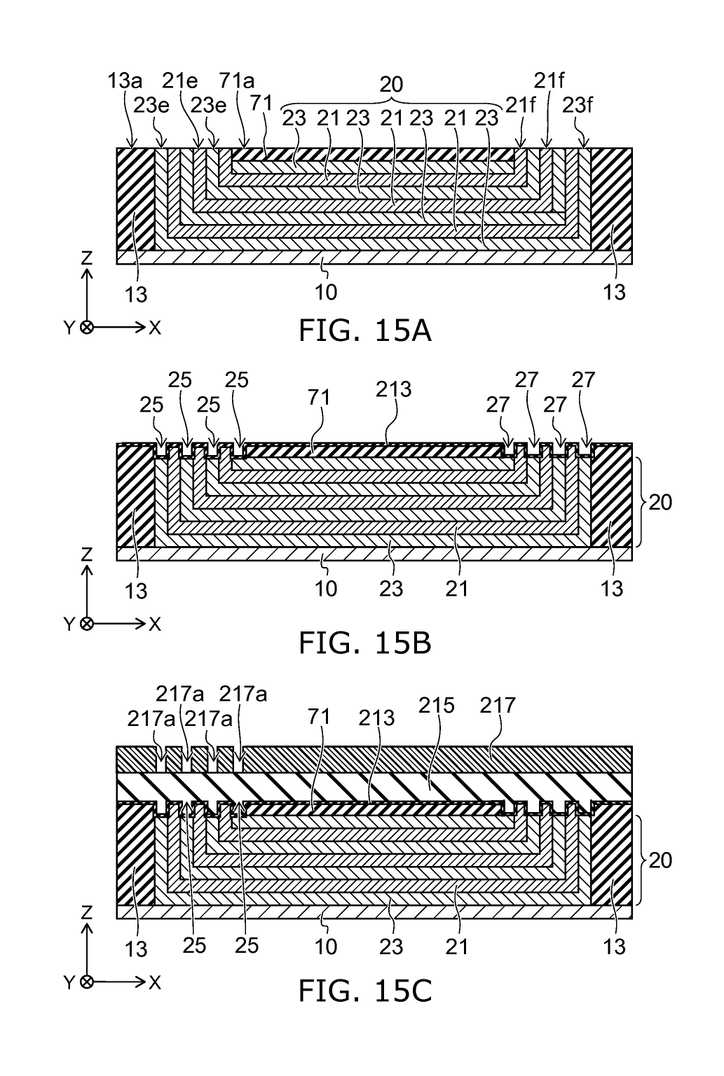

As shown in FIG. 15A, the upper ends of the n-type semiconductor layers 21 and the p-type semiconductor layers 23 is planarized. For example, parts of the n-type semiconductor layers 21 and the p-type semiconductor layers 23 formed on the insulating film 13 are removed by CMP. The insulating film 13 and the insulating film 71 serves as a stopper. Thus, the upper surface 13a of the insulating film 13 are in plane with the upper surface 71a of the insulating film 71. The upper end 21e, 21f of the n-type semiconductor layer 21 and the upper end 23e, 23f of the p-type semiconductor layer 23 are formed between the insulating film 13 and the insulating film 71.

As shown in FIG. 15B, the p-type semiconductor layer 23 is selectively removed to form trenches 25 and trenches 27. The depth of the trenches 25 and 27 is preferably equal to the thickness of the insulating film 71.

Then, an insulating film 213 is formed to cover the inner surface of the trench 25, 27 and the insulating film 13, 71. The insulating film 213 is a silicon oxide film, for example. Subsequently, an insulating film 215 is formed on the insulating film 213. The insulating film 215 fills the inside of the trench 25, 27. The insulating film 215 is a silicon oxide film, for example.

As shown in FIG. 15C, a resist film 217 is formed on the insulating film 215. The resist film 217 has an opening 217a above the trench 25. Then, the insulating film 215 and the insulating film 213 are selectively removed using the resist film 217 as an etching mask. Subsequently, the resist film 217 is removed.

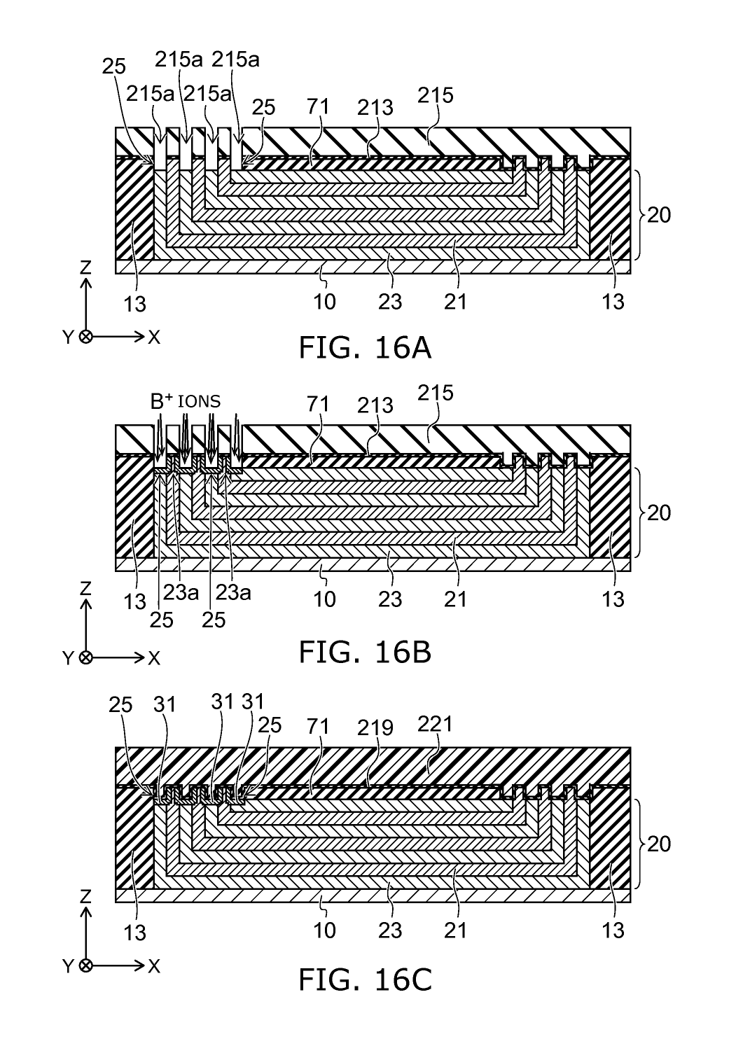

As shown in FIG. 16A, trenches 215a are formed in the insulating film 215. The trench 25 is reproduced in the lower part of each trench 215a. The trench 215a is in communication with the trench 25.

As shown in FIG. 16B, p-type impurities such as boron (B) are ion-implanted into the inner surface of the trench 25. Then, the insulating film 215 and the insulating film 213 are removed, and the ion-implanted p-type impurities are activated by heat treatment to form a p-type base region 31.

An insulating film 219 is formed to cover the inner surface of the trench 25 and the insulating film 13, 71. The insulating film 219 is a silicon oxide film, for example. Then, as shown in FIG. 16C, a resist film 221 is formed on the insulating film 219 to fill the inside of the trench 25.

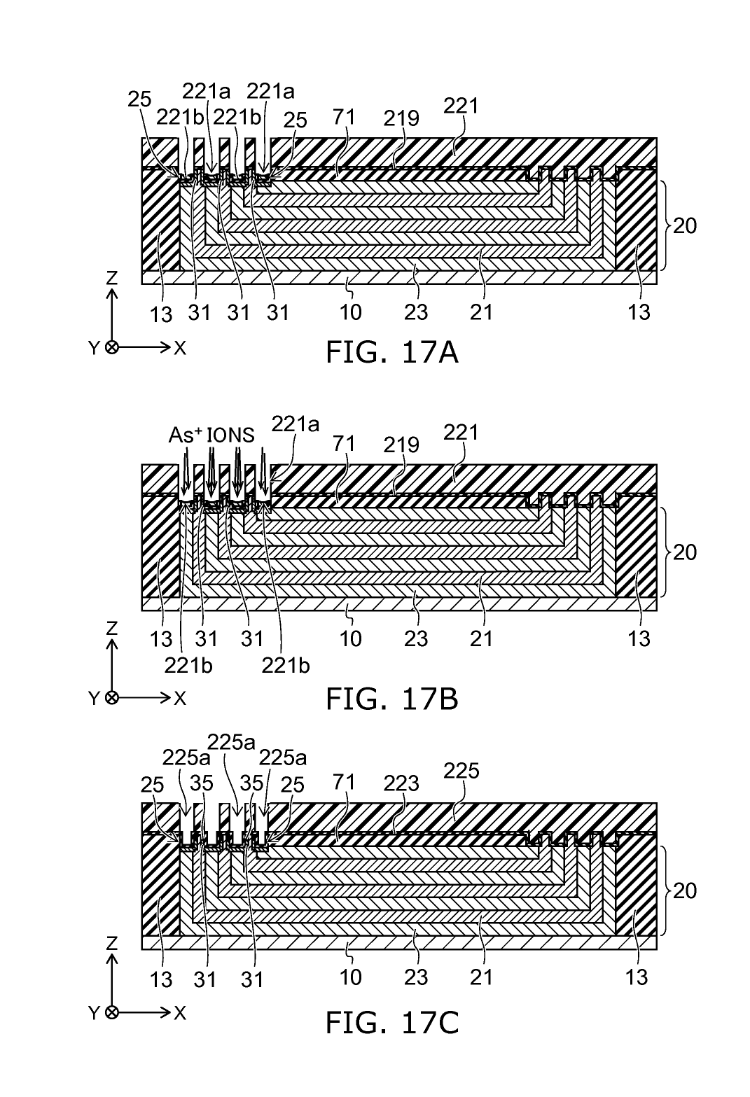

As shown in FIG. 17A, the portion of the resist film 221 above the trench 25 is selectively etched back to form an opening 221a, leaving a part 221b of the resist film 221 at the bottom of the opening 221a, and to expose the upper end of the p-type base region 31.

As shown in FIG. 17B, n-type impurities such as arsenic (As) are ion-implanted into the upper end of the p-type base region 31 through the opening 221a. Subsequently, the resist film 221 and the insulating film 219 are removed, and the ion-implanted n-type impurities are activated by heat treatment to form an n-type source region 35.

As shown in FIG. 17C, an insulating film 223 is formed to cover the inner surface of the trench 25 and the insulating film 13, 71. The insulating film 223 is a silicon oxide film, for example. Then, a resist film 225 is formed on the insulating film 223. The resist film 225 has an opening 225a in communication with the trench 25.

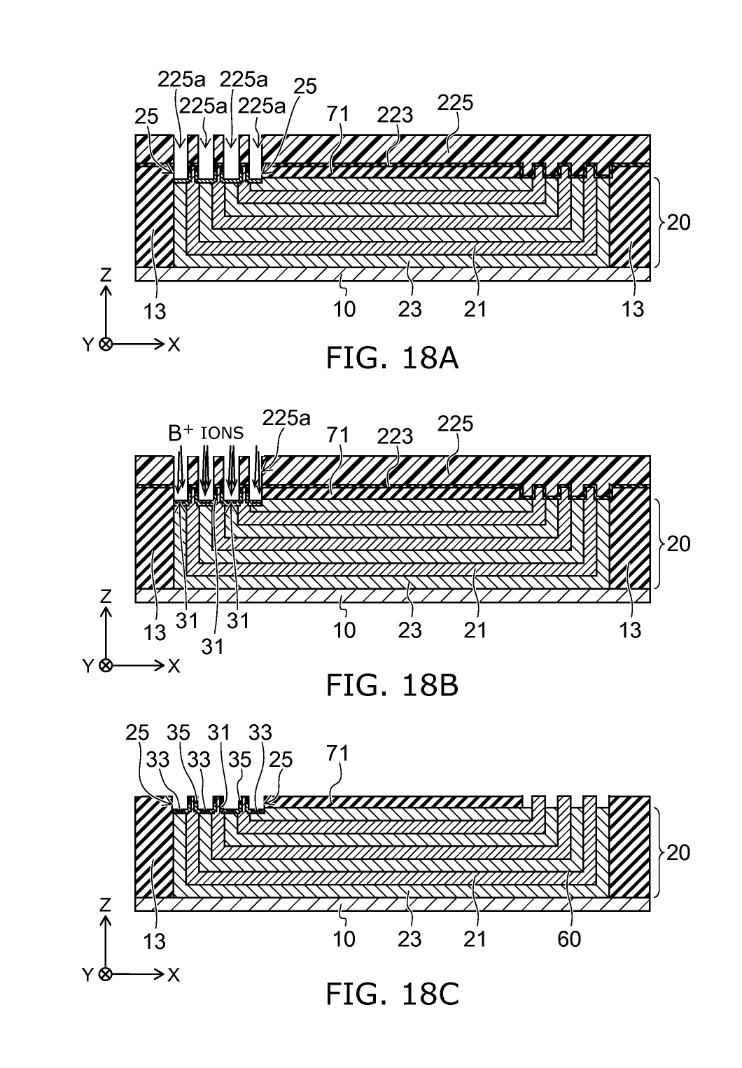

As shown in FIG. 18A, a portion of the insulating film 223 on the bottom surface of the trench 25 is removed via the opening 225a.

As shown in FIG. 18B, p-type impurities such as boron (B) are ion-implanted into the p-type base region 31 through the opening 225a. The p-type impurities are implanted into the bottom surface of the trench 25.

Then, the resist film 225 and the insulating film 223 are removed, and the ion-implanted p-type impurity is activated by heat treatment to form a p-type contact region 33.

As shown in FIG. 18C, the p-type contact region 33 is formed on the p-type base region 31 at the bottom surface of the trench 25.

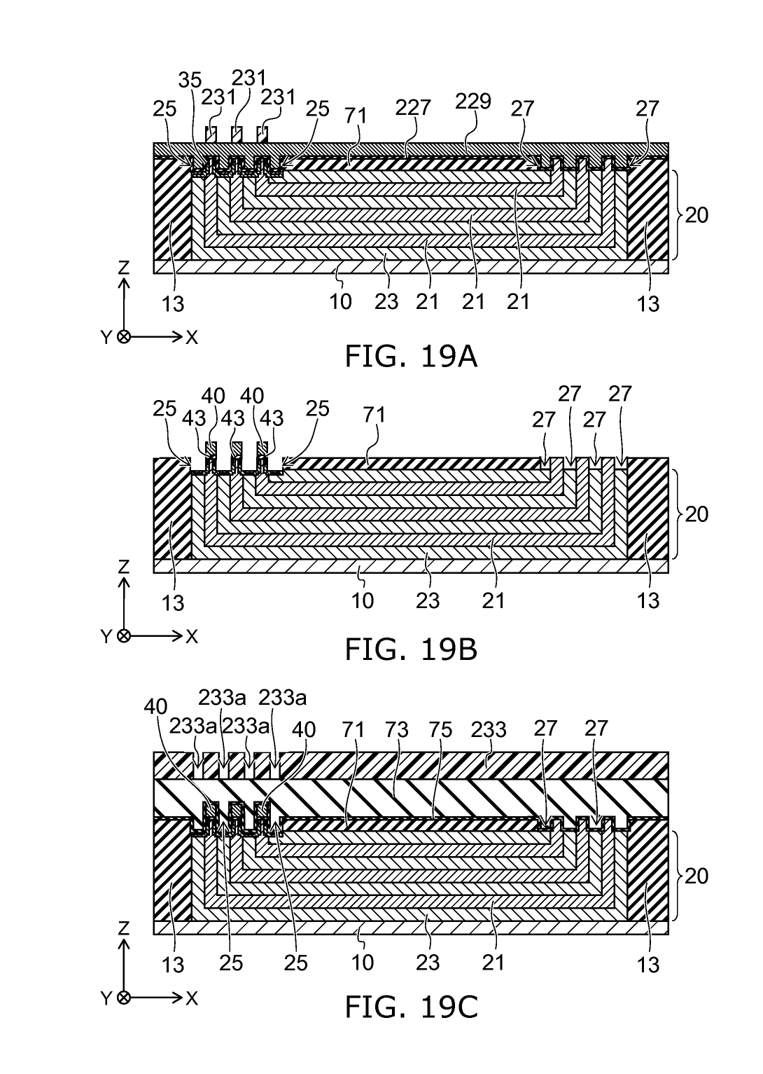

As shown in FIG. 19A, an insulating film 227 is formed to cover the inner surface of the trench 25, the inner surface of the trench 27, and the insulating film 13, 71. The insulating film 227 is a silicon oxide film, for example. Then, a conductive film 229 is formed on the insulating film 227. The conductive film 229 is a conductive polysilicon film, for example. Subsequently, a resist film 231 is formed on the conductive film 229. The resist film 231 is formed above the n-type semiconductor layer 21.

Then, the conductive film 229 and the insulating film 227 are selectively removed using the resist film 231 as an etching mask.

As shown in FIG. 19B, a gate electrode 40 and a gate insulating film 43 are formed on the n-type semiconductor layer 21. The gate electrode 40 is a part of the conductive film 229. The gate insulating film 43 is a part of the insulating film 227.

As shown in FIG. 19C, an insulating film 75 is formed to cover the inner surface of the trench 25, the inner surface of the trench 27, the gate electrode 40, and the insulating films 13 and 71. The insulating film 75 is a silicon oxide film, for example. Then, an insulating film 73 is formed on the insulating film 75. The insulating film 73 is formed so as to fill the inside of the trench 25 and the inside of the trench 27. The insulating film 73 is a silicon oxide film, for example. Subsequently, a resist film 233 is formed on the insulating film 73. The resist film 233 has an opening 233a formed above the trench 25.

Then, the insulating film 73 is selectively removed using the resist film 233 as an etching mask. Thus, a trench 73a is formed in the insulating film 73.

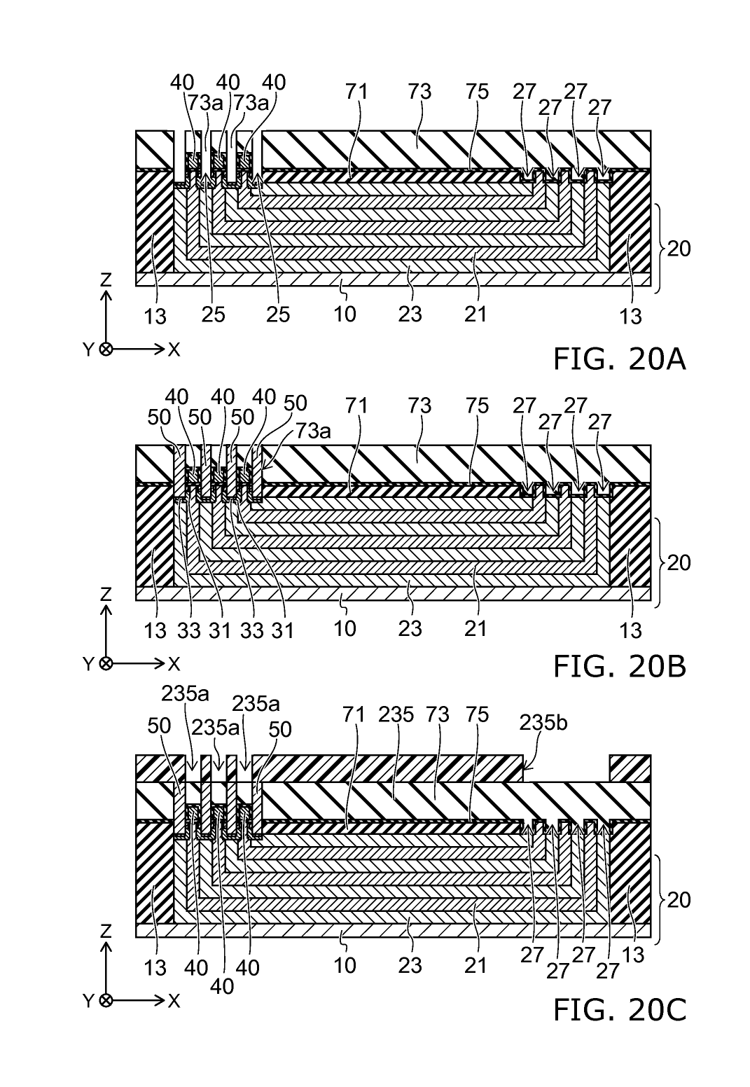

As shown in FIG. 20A, the trench 73a is in communication with the trench 25. That is, a portion of the insulating film 73 filling the trench 25 is removed, leaving a part of the insulating film 73 on the gate electrode 40.

Further, a portion of the insulating film 75 covering the inner surface of the trench 25 is removed. For example, isotropic dry etching is used to remove the portion exposed in the inner surface of the trench 25, leaving a portion covering the gate electrode 40.

As shown in FIG. 20B, a source electrode 50 is formed inside the trench 73a. For example, a metal film (not shown) is formed on the insulating film 73 to fill the trench 73a. The metal film is removed by CMP or etch-back. Thus, the source electrode 50 is formed in the trench 73a.

As shown in FIG. 20C, a resist film 235 is formed to cover the insulating film 73. The resist film 235 has openings 235a and 235b. The opening 235a is in communication with a portion of the insulating film 73 on the gate electrode. The opening 235b is formed above the region where the trench 27 is formed.

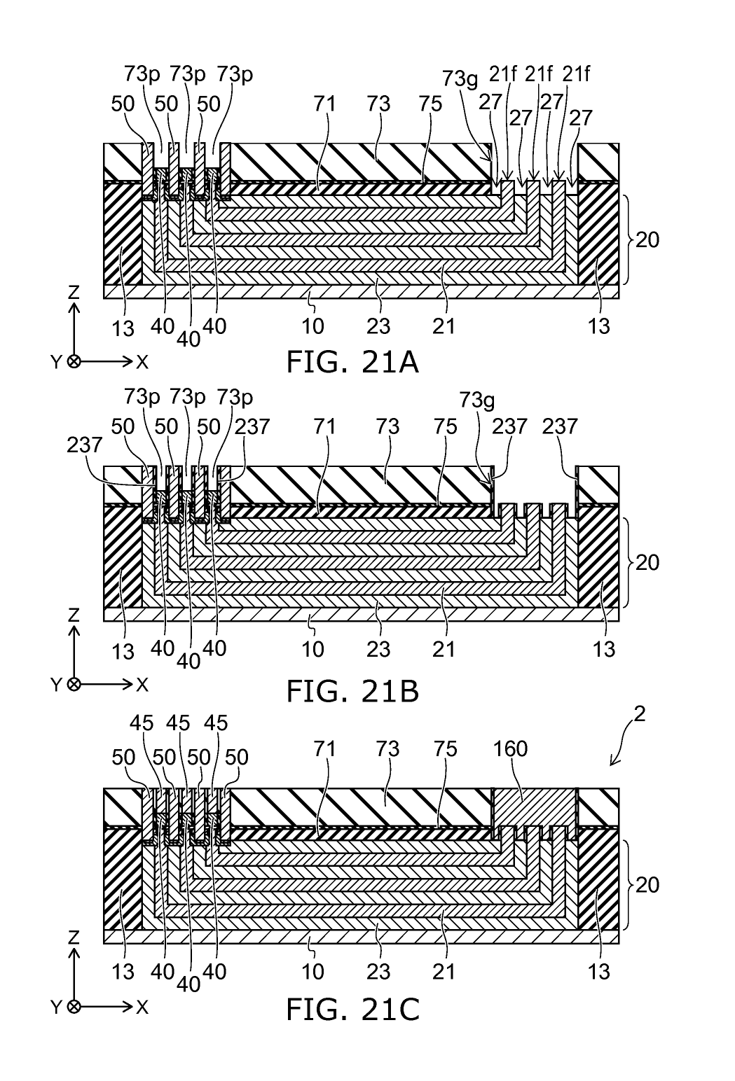

Then, the insulating film 73 is selectively removed using the resist film 235 as an etching mask. Thus, as shown in FIG. 21A, trenches 73p and 73q is formed in the insulating film 73. The trench 73p is in communication with the gate electrode 40. The trench 27 and the end part 21f of the n-type semiconductor layer 21 are exposed at the bottom of the trench 73q.

As shown in FIG. 21B, an insulating film 237 is formed on the inner wall of the trench 73p, 73q. For example, an insulating film 237 is formed to cover the trench 73p, the trench 73q, and the insulating film 73. Then, the insulating film 237 formed on the bottom surface of the trench 73p, the bottom surface of the trench 73q, and the upper surface of the insulating film 73 is removed by anisotropic dry etching, for example, leaving a portion on the inner wall of the trenches 73p and 73q. Thus, the gate electrode 40 is exposed at the bottom surface of the trench 73p. The upper end of the n-type semiconductor layer 21 and the upper end of the p-type semiconductor layer 23 is exposed at the bottom surface of the trench 73q. The insulating film 237 formed on the inner wall of the trench 73p electrically insulates the source electrode 50 from a gate interconnection 45 formed later.

As shown in FIG. 21C, the gate wiring 45 is formed inside the trench 73p. A drain electrode 160 is formed inside the trench 73g. For example, a metal film covering the insulating film 73 is formed to fill the trench 73p and the trench 73g. Then, the metal film 137 on the insulating film 73 is removed, leaving portions embedded in the trenches 73p and 73g. Thus, a gate interconnection 45 and a drain electrode 160 are formed in the trench 73p and the trench 73g. Thus, the semiconductor device 2 is completed as shown in FIG. 21C.

As described above, according to the embodiments, the lateral MOSFET can be achieved, which has the super-junction structure. Since the super-junction structure is formed by stacking n-type semiconductor layers 21 and p-type semiconductor layers 23, it is possible to achieve the lower on-resistance by the super-junction structure beyond the size limit of the miniaturization using photolithography.

The source electrode 50 is formed inside the trench 25. The source electrode 50 is in contact with the p-type contact region 33 and the n-type source region 35 in the trench 25. Thus, each contact resistance is reduced, and the on-resistance may further be reduced. This may also improve the avalanche breakdown voltage.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

1. A semiconductor device comprising:
an underlying layer;
first semiconductor layers of a first conductivity type arranged in a first direction perpendicular to the underlying layer, the first semiconductor layers having first end surfaces;
a second semiconductor layer of a second conductivity type disposed between the adjacent first semiconductor layers, the second semiconductor layer having a second end surface between the adjacent first semiconductor layers;
a first electrode facing each first end surface of the adjacent first semiconductor layers via an insulating film;
a second electrode in contact with each side surface of the adjacent first semiconductor layers and the second end surface;
a first semiconductor region of the second conductivity type between the second electrode and each of the adjacent first semiconductor layers, the first semiconductor region facing the first electrode via the insulating film; and
a second semiconductor region of the first conductivity type in the first semiconductor region between the second electrode and each of the adjacent first semiconductor layers, the second semiconductor region facing the first electrode via the insulating film, and electrically connected to the second electrode.

2. The device according to claim 1, wherein each of the adjacent first semiconductor layers and the second semiconductor layer include a first portion extending in a second direction parallel to the underlying layer, and a second portion extending in the first direction.

3. The device according to claim 1, wherein the first end surfaces and the second end surface are in parallel to the underlying layer.

4. The device according to claim 3, wherein the second end surface is set back toward the underlying layer from the each first end surface of the adjacent first semiconductor layers.

5. The device according to claim 4, wherein
the second electrode extends in the first direction and has a first end in contact with the second end surface, and a second end opposite to the second end, and
a distance between the underlying layer and the second end is wider than a distance between the underlying layer and the each first end surface of the adjacent first semiconductor layers.

6. The device according to claim 1, wherein the first semiconductor region has a surface exposed in the each first end surface of the adjacent first semiconductor layers, and another surface exposed in each side surface of the adjacent first semiconductor layers.

7. The device according to claim 6, wherein a surface of the second semiconductor region is exposed in the first end surface and in the another surface.

8. The device according to claim 7, wherein the second electrode is in contact with the second semiconductor region exposed in the another surface.

9. The device according to claim 1, wherein
The each first end surface includes surfaces of the first semiconductor region, the second semiconductor region, and any one of the adjacent first semiconductor layers, and
the first semiconductor region is exposed in the each first end surface between the any one of the adjacent first semiconductor layers and the second semiconductor region.

10. The device according to claim 9, wherein the first electrode faces the first semiconductor region, the second semiconductor region, and the any one of the first semiconductor layers via the insulating film.

11. The device according to claim 1, further comprising:
a third semiconductor region of the second conductivity type selectively provided in the first semiconductor region, the third semiconductor region being in contact with the second electrode.

12. The device according to claim 11, wherein the second end surface includes a surface of the third semiconductor region.

13. The device according to claim 10, wherein the third semiconductor region has a concentration of the second conductivity type impurities higher than a concentration of the second conductivity type impurities of the first semiconductor region.

14. The device according to claim 1, further comprising:
a third semiconductor layer of the first conductivity type selectively provided on the underlying layer and connected to each end of the adjacent first semiconductor layers that is different from the first end surfaces, and an end of the second semiconductor layer that is different from the second end surface.

15. The device according to claim 1, further comprising:
a third electrode provided on the underlying layer and electrically connected to each end of the adjacent first semiconductor layers that is different from the first end surfaces, and an end of the second semiconductor layer that is different from the second end surface.

16. The device according to claim 1, wherein a total width in the first direction of the any one of the first semiconductor layers and the second semiconductor layer is 1 μm or less.
